(19) United States
(12) Patent Application Publication
(10) Pub. No.: US 2024/0120364 A1
(43) Pub. Date: Apr. 11, 2024

(54) IMAGING DEVICE AND METHOD FOR MANUFACTURING THE SAME

(71) Applicant: SONY GROUP CORPORATION, Tokyo (JP)

(72) Inventor: Tomohiro SUGIYAMA, Kanagawa (JP)

(73) Assignee: SONY GROUP CORPORATION, Tokyo (JP)

(21) Appl. No.: 18/264,784

(22) PCT Filed: Jan. 25, 2022
(86) PCT No.: PCT/JP2022/002709

§ 371 Date: Aug. 9, 2023

(30) Foreign Application Priority Data
Feb. 18, 2021 (JP) 2021-024575

(51) Int. Cl. H01L 27/146

(52) U.S. Cl. CPC H01L 27/14636; H01L 27/14618; H01L 27/14634; H01L 27/14683

(57) ABSTRACT

An imaging device capable of suppressing at least one of defects caused by a passivation film is provided. An imaging device according to an embodiment of the present disclosure includes a substrate, a pixel circuit provided on the substrate, a through silicon via that penetrates the substrate and is electrically connected to the pixel circuit, and a passivation film that covers the through silicon via. The passivation film contains at least silicon.

### TECHNICAL FIELD

The present disclosure relates to an imaging device and a method for manufacturing the same.

### BACKGROUND ART

A wafer level chip size package (WLCSP) process, which is one of manufacturing processes of an imaging device, includes a solder mask (SM) process. In the SM process, a through silicon via (TSV) containing copper referred to as a redistribution layer (RDL) and a connection terminal are covered with a passivation film. Conventionally, a resin is used in the passivation film in order to prevent corrosion of the redistribution layer and ensure insulation. Furthermore, solder is welded to the connection terminal.

### CITATION LIST

### Patent Document

Patent Document 1: Japanese Patent Application Laid-Open No. H11-288935

### SUMMARY OF THE INVENTION

### Problems to be Solved by the Invention

When a passivation film is a resin film, there is a case where a through silicon via is deformed by a stress of the resin. In this case, a so-called spot defect in which a spot generated by deformation of the through silicon via appears in an image obtained by inspecting an imaging device from an incident light side might occur.

Furthermore, when a temperature cycle test, which is one of reliability tests regarding temperature changes, is performed, there is a case where solder deforms by a stress associated with expansion and contraction of the resin contained in the passivation film. In this case, when a crack occurs between a connection terminal and the solder, conduction failure might occur.

The present disclosure provides an imaging device capable of suppressing at least one of defects caused by the passivation film, and a method for manufacturing the same.

### Solutions to Problems

An imaging device according to an embodiment of the present disclosure includes a substrate, a pixel circuit provided on the substrate, a through silicon via that penetrates the substrate and is electrically connected to the pixel circuit, and a passivation film that covers the through silicon via. The passivation film contains at least silicon.

The passivation film may contain silicon oxide (SiO₂), silicon nitride (SiN), or silicon carbonitride (SiCN).

The passivation film may contain a porous low-k material.

The porous low-k material may be fluorine-doped silicon oxide (SiOF) or carbon-doped silicon oxide (SiOC).

A thickness of the passivation film may be 30 nm to 50 nm.

The substrate may include a first substrate and a second substrate stacked on the first substrate,
the pixel circuit may be provided on the first substrate, and
the through silicon via may be provided on the second substrate.

The through silicon via may have a recessed shape recessed toward the first substrate.

The through silicon via may have a tapered shape in which an opening diameter of the recessed shape is narrower than a bottom width of the recessed shape.

A connection terminal that protrudes from the second substrate and is electrically connected to the through silicon via may be further included, in which
the passivation film may cover a side surface of the connection terminal.

Another imaging device according to an embodiment of the present disclosure includes a substrate, a pixel circuit provided on the substrate, a connection terminal that protrudes from the substrate, and a passivation film that covers a side surface of the connection terminal. The passivation film contains at least silicon.

The passivation film may contain silicon oxide (SiO₂), silicon nitride (SiN), or silicon carbonitride (SiCN).

The passivation film may contain a porous low-k material.

The porous low-k material may be fluorine-doped silicon oxide (SiOF) or carbon-doped silicon oxide (SiOC).

A thickness of the passivation film may be 30 nm to 50 nm.

The substrate may include a first substrate and a second substrate stacked on the first substrate,
the pixel circuit may be provided on the first substrate, and
the connection terminal may be provided on the second substrate.

The connection terminal may include a recess, and a solder ball may be welded to the recess.

A method for manufacturing an imaging device according to an embodiment of the present disclosure forms a through silicon via that penetrates a substrate and is electrically connected to a pixel circuit, and covers the through silicon via with a passivation film containing at least silicon.

The passivation film may be formed by chemical vapor deposition (CVD) or atomic layer deposition (ALD).

The passivation film may contain silicon oxide (SiO₂), silicon nitride (SiN), or silicon carbonitride (SiCN).

The passivation film may contain a porous low-k material.

### BRIEF DESCRIPTION OF DRAWINGS

FIG. 1 is a diagram schematically illustrating an internal structure of an imaging device according to a first embodiment.

FIG. 2A is a layout diagram illustrating an example of circuit arrangement of the imaging device according to the first embodiment.

FIG. 2B is a layout diagram illustrating another example of the circuit arrangement of the imaging device according to the first embodiment.

FIG. 3 is a plane view illustrating a circuit configuration of the imaging device.

FIG. 4 is an equivalent circuit diagram of a pixel.

FIG. 5 is an enlarged cross-sectional view of a substantial part of a laminated substrate.

FIG. 6A is a cross-sectional view illustrating a forming process of a through silicon via and a connection terminal in the first embodiment.

FIG. 6B is a cross-sectional view illustrating a peeling process of a resist in the first embodiment.

FIG. 6C is a cross-sectional view illustrating a removing process of a seed layer in the first embodiment.

FIG. 6D is a cross-sectional view illustrating a film forming process of a passivation film in the first embodiment.

FIG. 6E is a cross-sectional view illustrating an applying process of the resist in the first embodiment.

FIG. 6F is a cross-sectional view illustrating a polishing process of the resist in the first embodiment.

FIG. 6G is a cross-sectional view illustrating a peeling process of the resist in the first embodiment.

FIG. 7A is a diagram illustrating an example of a mounting state of the imaging device according to the first embodiment.

FIG. 7B is a partially enlarged view of FIG. 7A.

FIG. 8A is a cross-sectional view illustrating an exposing process of a resist in a second embodiment.

FIG. 8B is a cross-sectional view illustrating the exposing process of the resist in the second embodiment.

FIG. 8C is a cross-sectional view illustrating a removing process of an exposed portion of a passivation film in the second embodiment.

FIG. 8D is a cross-sectional view illustrating a peeling process of the resist in the second embodiment.

FIG. 9A is a cross-sectional view illustrating a structure of a substantial part of an imaging device according to a third embodiment.

FIG. 9B is a plane view illustrating the structure of the substantial part of the imaging device according to the third embodiment.

FIG. 10A is a cross-sectional view illustrating an exposing process of a resist in the third embodiment.

FIG. 10B is a cross-sectional view illustrating a developing process of the resist in the third embodiment.

FIG. 10C is a cross-sectional view illustrating an electroplating process of a seed layer in the third embodiment.

FIG. 10D is a cross-sectional view illustrating a peeling process of the resist in the third embodiment.

FIG. 10E is a cross-sectional view illustrating an exposing process of the resist in the third embodiment.

FIG. 10F is a cross-sectional view illustrating a developing process of the resist in the third embodiment.

FIG. 10G is a cross-sectional view illustrating an electroplating process of a base layer in the third embodiment.

FIG. 10H is a cross-sectional view illustrating a removing process of the resist and seed layer in the third embodiment.

FIG. 10I is a cross-sectional view illustrating a film forming process of a passivation film in the third embodiment.

FIG. 10J is a cross-sectional view illustrating an exposing process of the resist in the third embodiment.

FIG. 10K is a cross-sectional view illustrating a developing process of the resist in the third embodiment.

FIG. 10L is a cross-sectional view illustrating a removing process of an exposed portion of the passivation film in the third embodiment.

FIG. 10M is a cross-sectional view illustrating a peeling process of the resist in the third embodiment.

FIG. 11 is a cross-sectional view illustrating a shape of a solder ball before being joined to a relay substrate in the third embodiment.

FIG. 12A is a cross-sectional view illustrating the shape of the solder ball after being joined to the relay substrate in the third embodiment.

FIG. 12B is a plane view illustrating the shape of the solder ball after being joined to the relay substrate in the third embodiment.

FIG. 13A is a diagram illustrating an example of a mounting state of the imaging device according to the third embodiment.

FIG. 13B is a partially enlarged view of FIG. 13A.

FIG. 14 is a cross-sectional view illustrating a schematic structure of an imaging device according to a fourth embodiment.

FIG. 15 is a cross-sectional view illustrating a schematic structure of an imaging device according to a fifth embodiment.

FIG. 16 is a block diagram depicting an example of schematic configuration of a vehicle control system.

FIG. 17 is an explanatory diagram illustrating an example of installation positions of an outside-vehicle information detecting section and an imaging section.

### MODE FOR CARRYING OUT THE INVENTION

### First Embodiment

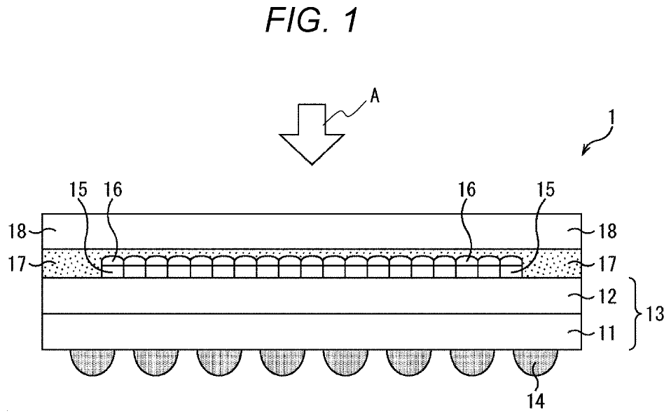

FIG. 1 is a diagram schematically illustrating an internal structure of an imaging device according to a first embodiment. An imaging device 1 illustrated in FIG. 1 includes a laminated substrate 13 obtained by stacking a logic substrate 11 and a pixel sensor substrate 12. The logic substrate 11 corresponds to a first substrate, and the pixel sensor substrate 12 corresponds to a second substrate. The imaging device 1 converts light incident from above (refer to arrow A) into an electric signal to output.

A plurality of balls 14 is formed on a bottom surface of the logic substrate 11. The plurality of balls 14 is electrically connected to a relay substrate not illustrated.

On an upper surface of the pixel sensor substrate 12, red (R), green (G), or blue (B) color filters 15 and on-chip lenses 16 are formed. Furthermore, the pixel sensor substrate 12 is connected to a glass protection substrate 18 for protecting the on-chip lens 16 via a glass seal resin 17 in a cavity-less structure.

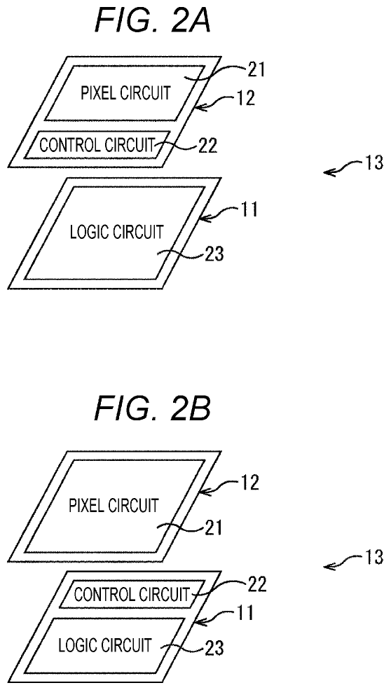

FIG. 2A is a layout diagram illustrating an example of circuit arrangement of the imaging device 1 according to this embodiment. In the layout diagram illustrated in FIG. 2A, a pixel circuit 21 and a control circuit 22 are arranged on the pixel sensor substrate 12. Furthermore, a logic circuit 23 is arranged on the logic substrate 11.

In the pixel circuit 21, a plurality of pixels that photoelectrically converts incident light is two-dimensionally arrayed. The control circuit 22 controls an operation of each pixel. The logic circuit 23 includes a signal processing circuit and the like that processes a pixel signal output from each pixel.

FIG. 2B is a layout diagram illustrating another example of the circuit arrangement of the imaging device 1 according to this embodiment. In the layout diagram illustrated in FIG. 2B, only the pixel circuit 21 is arranged on the pixel sensor substrate 12. In contrast, the control circuit 22 and the logic circuit 23 are arranged on the logic substrate 11.

According to the layout diagrams illustrated in FIGS. 2A and 2B, both the control circuit 22 and the logic circuit 23 are, or the logic circuit 23 is arranged on a semiconductor substrate other than that of the pixel circuit 21. Therefore, a size of the imaging device 1 can be made compact as compared with a case where the circuits from the pixel circuit 21 to the logic circuit 23 are planarly arranged on one semiconductor substrate.

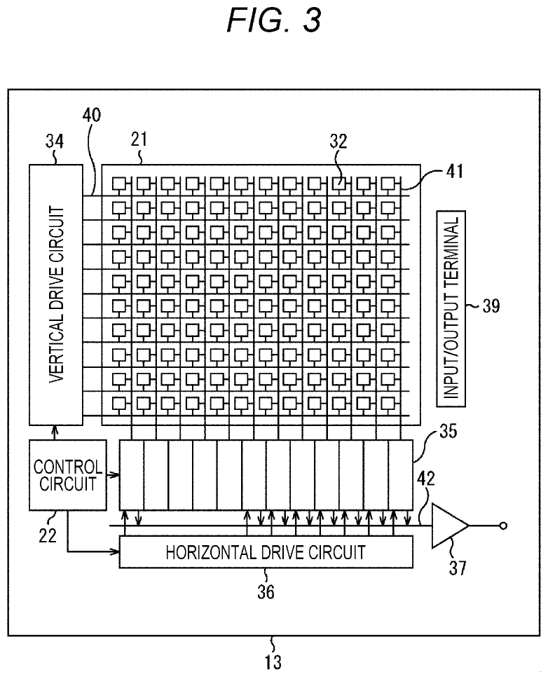

FIG. 3 is a plane view illustrating a circuit configuration of the imaging device 1. As illustrated in FIG. 3, a plurality of pixels 32 is two-dimensionally arrayed on the pixel circuit 21.

The control circuit 22 receives an input clock and data giving a command of an operation mode and the like, and outputs data of internal information and the like of the laminated substrate 13. That is, the control circuit 22 generates a clock signal and a control signal serving as references of operations of a vertical drive circuit 34, a column signal processing circuit 35, a horizontal drive circuit 36 and the like on the basis of a vertical synchronization signal, a horizontal synchronization signal, and a master clock. Then, the control circuit 22 outputs the generated clock signal and control signal to the vertical drive circuit 34, the column signal processing circuit 35, the horizontal drive circuit 36 and the like.

The vertical drive circuit 34, the column signal processing circuit 35, the horizontal drive circuit 36, and an output circuit 37 are included in the logic circuit 23. The vertical drive circuit 34 includes, for example, a shift register, selects predetermined pixel drive wiring 40, supplies a pulse for driving the pixels 32 to the selected pixel drive wiring 40, and drives the pixels 32 in units of rows. That is, the vertical drive circuit 34 sequentially selects to scan each pixel 32 in the pixel circuit 21 in a vertical direction in units of row, and supplies a pixel signal based on a signal charge generated according to a received light amount by a photoelectric conversion unit of each pixel 32 to the column signal processing circuit 35 via a vertical signal line 41.

The column signal processing circuit 35 is arranged for each column of the pixels 32 and performs signal processing such as noise removal on the signals output from the pixels 32 of one row for each pixel column. For example, the column signal processing circuit 35 performs signal processing such as correlated double sampling (CDS) for removing pixel-specific fixed pattern noise, or AD conversion for converting an analog signal to a digital signal.

The horizontal drive circuit 36 includes, for example, a shift register, selects each of the column signal processing circuits 35 in turn by sequentially outputting horizontal scanning pulses, and allows each of the column signal processing circuits 35 to output the pixel signal from to a horizontal signal line 42.

The output circuit 37 performs signal processing on the signals sequentially supplied from each of the column signal processing circuits 35 via the horizontal signal line 42 to output. There is a case where the output circuit 37 performs only buffering, for example, and a case where this performs black level adjustment, column variation correction, various types of digital signal processing and the like. An input/output terminal 39 exchanges signals with the outside.

The imaging device 1 formed in the above-described manner is a CMOS image sensor referred to as a column AD type in which the column signal processing circuit 35 that performs CDS processing and AD conversion processing is arranged for each pixel column.

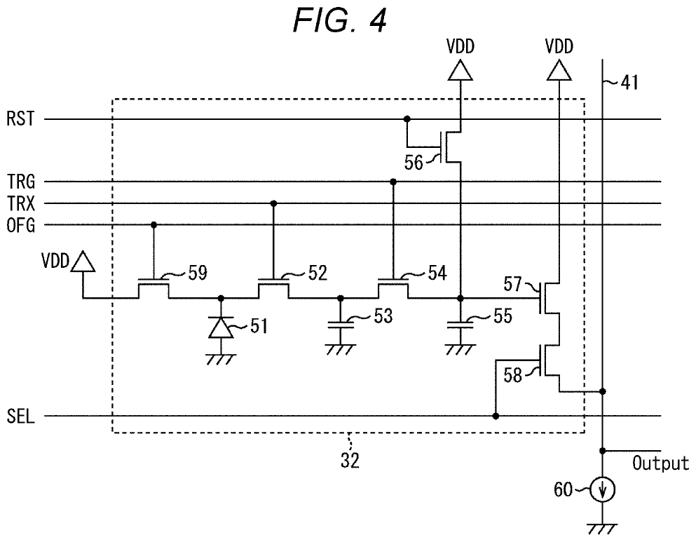

FIG. 4 is an equivalent circuit diagram of the pixel 32. The pixel 32 illustrated in FIG. 4 implements an electronic global shutter function.

The pixel 32 includes a photodiode 51, a first transfer transistor 52, a memory unit 53, a second transfer transistor 54, a floating diffusion region (FD) 55, a reset transistor 56, an amplification transistor 57, a selection transistor 58, and a discharge transistor 59.

The photodiode 51 is the photoelectric conversion unit that generates the charge (signal charge) corresponding to the received light amount to accumulate. An anode terminal of the photodiode 51 is grounded, and a cathode terminal thereof is connected to the memory unit 53 via the first transfer transistor 52. Furthermore, the cathode terminal of the photodiode 51 is also connected to the discharge transistor 59 for discharging an unnecessary charge.

When turned on by a transfer signal TRX, the first transfer transistor 52 reads the charge generated by the photodiode 51 to transfer to the memory unit 53. The memory unit 53 is a charge holding unit that temporarily holds the charge until the charge is transferred to the FD 55.

When turned on by a transfer signal TRG, the second transfer transistor 54 reads the charge held in the memory unit 53 to transfer to the FD 55.

The FD 55 is a charge holding unit that holds the charge read from the memory unit 53 in order to read the same as the signal. When turned on by a reset signal RST, the reset transistor 56 resets potential of the FD 55 by discharging the charge accumulated in the FD 55 to a constant voltage source VDD.

The amplification transistor 57 outputs the pixel signal corresponding to the potential of the FD 55. That is, the amplification transistor 57 forms a source follower circuit with a load MOS 60 as a constant current source. The pixel signal indicates a level corresponding to the charge accumulated in the FD 55 and is output from the amplification transistor 57 to the column signal processing circuit 35 (refer to FIG. 3) via the selection transistor 58. The load MOS 60 is arranged, for example, in the column signal processing circuit 35.

The selection transistor 58 is turned on when the pixel 32 is selected by a selection signal SEL, and outputs the pixel signal of the pixel 32 to the column signal processing circuit 35 via the vertical signal line 41.

When turned on by a discharge signal OFG, the discharge transistor 59 discharges the unnecessary charge accumulated in the photodiode 51 to the constant voltage source VDD.

The transfer signals TRX and TRG, the reset signal RST, the discharge signal OFG, and the selection signal SEL are supplied from the vertical drive circuit 34 via the pixel drive wiring 40.

Hereinafter, an operation of the pixel 32 is briefly described.

First, before exposure is started, a high-level discharge signal OFG is supplied to the discharge transistor 59, so that the discharge transistor 59 is turned on. Therefore, the charge accumulated in the photodiode 51 is discharged to the constant voltage source VDD, and the photodiodes 51 of all the pixels are reset.

After the photodiodes 51 are reset, when the discharge transistor 59 is turned off by a low-level discharge signal OFG, exposure is started in all the pixels of the pixel circuit 21.

When a predetermined exposure time determined in advance elapses, the first transfer transistor 52 is turned on by the transfer signal TRX, and the charge accumulated in the photodiode 51 is transferred to the memory unit 53 in all the pixels of the pixel circuit 21.

After the first transfer transistor 52 is turned off, the charge held in the memory unit 53 of each pixel 32 is sequentially read to the column signal processing circuit 35 in units of rows. In a read operation, the second transfer transistor 54 of the pixel 32 of the read row is turned on by the transfer signal TRG, and the charge held in the memory unit 53 is transferred to the FD 55. Then, when the selection transistor 58 is turned on by the selection signal SEL, the pixel signal indicating the level corresponding to the charge accumulated in the FD 55 is output from the amplification transistor 57 to the column signal processing circuit 35 via the selection transistor 58.

As described above, the imaging device 1 according to this embodiment may operate (image) as a global shutter type. In the global shutter type, the exposure time is set to be the same in all the pixels of the pixel circuit 21, and after the exposure ends, the charge is temporarily held in the memory unit 53 and sequentially read in units of rows.

Note that, the circuit configuration of the pixel 32 is not limited to the configuration illustrated in FIG. 4. For example, the pixel 32 may have a circuit configuration, without the memory unit 53, that performs a so-called rolling shutter type operation of accumulating the charge in the FD 55 at different timings among the plurality of pixels 32.

Furthermore, the pixel 32 can have a shared pixel structure in which some pixel transistors are shared by a plurality of pixels. For example, a configuration in which the first transfer transistor 52, the memory unit 53, and the second transfer transistor 54 are included in units of pixels 32, and the FD 55, the reset transistor 56, the amplification transistor 57, and the selection transistor 58 are shared by a plurality of pixels and the like such as four pixels may be adopted.

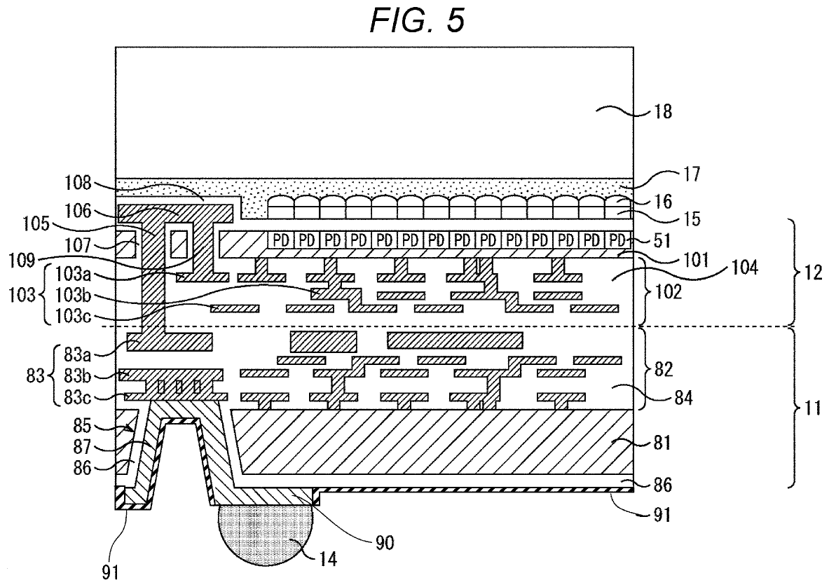

FIG. 5 is an enlarged cross-sectional view of a substantial part of the laminated substrate 13. Hereinafter, a cross-sectional structure of the laminated substrate 13 is described with reference to FIG. 5.

In the logic substrate 11, a multilayer wiring layer 82 is formed on an upper side (pixel sensor substrate 12 side) of a silicon substrate 81, for example. The multilayer wiring layer 82 can form the control circuit 22 and the logic circuit 23 illustrated in FIG. 2.

The multilayer wiring layer 82 includes a plurality of wiring layers 83 and an interlayer insulating film 84. The plurality of wiring layers 83 includes an uppermost wiring layer 83a closest to the pixel sensor substrate 12, an intermediate wiring layer 83b, a lowermost wiring layer 83c closest to the silicon substrate 81 and the like. In contrast, the interlayer insulating film 84 is formed between the wiring layers 83.

Each wiring layer 83 is formed by using, for example, copper (Cu), aluminum (Al), tungsten (W) and the like. The interlayer insulating film 84 is formed by using, for example, a silicon oxide film, a silicon nitride film and the like. In each of the plurality of wiring layers 83 and the interlayer insulating film 84, all the layers may include the same material, or two or more materials may be used depending on the layers.

A through hole 85 penetrating the silicon substrate 81 is formed at a predetermined position of the silicon substrate 81. A through silicon via 87 is formed on an inner wall of the through hole 85 via an insulating film 86. The insulating film 86 can be formed by using, for example, a silicon oxide (SiO₂) film, a silicon nitride (SiN) film and the like.

The through silicon via 87 is connected to a connection terminal 90 protruding from a lower surface side of the silicon substrate 81. Each of the through silicon via 87 and connection terminal 90 is a part of a redistribution layer (RDL). The solder ball 14 is joined to a surface (bottom surface) of the connection terminal 90. The through silicon via 87 and the connection terminal 90 can be formed, for example, by using a conductor such as copper (Cu), tungsten (W), titanium (Ti), tantalum (Ta), a titanium tungsten alloy (TiW), and polysilicon.

Furthermore, on the lower surface side of the silicon substrate 81, a passivation film 91 covers the through silicon via 87, a side surface of the connection terminal 90 (a surface other than a joining surface to the solder ball 14), and the insulating film 86. The passivation film 91 contains at least silicon. For example, the passivation film 91 is an insulating film containing silicon oxide (SiO₂), silicon nitride (SiN), or silicon carbonitride (SiCN). Furthermore, the passivation film 91 may be an insulating film containing a porous low-k material such as fluorine-doped silicon oxide (SiOF) or carbon-doped silicon oxide (SiOC).

In contrast, in the pixel sensor substrate 12, a multilayer wiring layer 102 is formed on a lower side (logic substrate 11 side) of the silicon substrate 101. The multilayer wiring layer 102 can form the pixel circuit 21 illustrated in FIG. 2.

The multilayer wiring layer 102 includes a plurality of wiring layers 103 and an interlayer insulating film 104. The plurality of wiring layers 103 includes an uppermost wiring layer 103a closest to the silicon substrate 101, an intermediate wiring layer 103b, a lowermost wiring layer 103c closest to the logic substrate 11 and the like. In contrast, the interlayer insulating film 104 is formed between the wiring layers 103.

As the material of the plurality of wiring layers 103 and the interlayer insulating film 104, a material of a type similar to that of the wiring layer 83 and the interlayer insulating film 84 described above can be adopted. Furthermore, the plurality of wiring layers 103 and the interlayer insulating film 104 may be formed by using one material or two or more materials as is the case with the wiring layer 83 and the interlayer insulating film 84 described above.

Note that, in FIG. 5, the multilayer wiring layer 102 of the pixel sensor substrate 12 includes the wiring layers 103 of three layers, and the multilayer wiring layer 82 of the logic substrate 11 includes the wiring layers 83 of four layers. However, the total number of wiring layers is not limited thereto, and any number of layers can be formed.

In the silicon substrate 101, the photodiode 51 formed by PN junction is formed for each pixel 32.

Furthermore, although not illustrated in FIG. 5, a plurality of pixel transistors such as the first transfer transistor 52 and the second transfer transistor 54, the memory unit 53 and the like are also formed in the multilayer wiring layer 102 and the silicon substrate 101.

At a predetermined position of the silicon substrate 101 at which the color filter 15 and the on-chip lens 16 are not formed, a through silicon via 109 connected to the wiring layer 103a of the pixel sensor substrate 12 and a through silicon via 105 connected to the wiring layer 83a of the logic substrate 11 are formed.

The through silicon via 105 and the through silicon via 109 are connected to each other by connection wiring 106 formed on an upper surface of the silicon substrate 101. Furthermore, an insulating film 107 is formed between each of the through silicon via 109 and through silicon via 105 and the silicon substrate 101. Moreover, on the upper surface of the silicon substrate 101, the color filter 15 and the on-chip lens 16 are formed via an insulating film (planarization film) 108.

As described above, the laminated substrate 13 according to this embodiment has a laminated structure obtained by adhering a multilayer wiring layer 82 side of the logic substrate 11 to a multilayer wiring layer 102 side of the pixel sensor substrate 12. In FIG. 5, a joining surface on which the multilayer wiring layer 82 of the logic substrate 11 and the multilayer wiring layer 102 of the pixel sensor substrate 12 are adhered to each other is indicated by a broken line.

Furthermore, in the laminated substrate 13 of the imaging device 1, the wiring layer 103 of the pixel sensor substrate 12 and the wiring layer 83 of the logic substrate 11 are connected to each other by two through silicon vias of the through silicon via 109 and the through silicon via 105, and the wiring layer 83 of the logic substrate 11 and the solder ball 14 are connected to each other by the through silicon via 87 and the connection terminal 90. Therefore, a plane surface area of the imaging device 1 can be extremely minimized.

Moreover, adhering the laminated substrate 13 to the glass protection substrate 18 with the glass seal resin 17 in the cavity-less structure allows a reduction in height, too.

Therefore, according to the imaging device 1 illustrated in FIG. 1, a semiconductor device (semiconductor package) that is further downsized can be achieved.

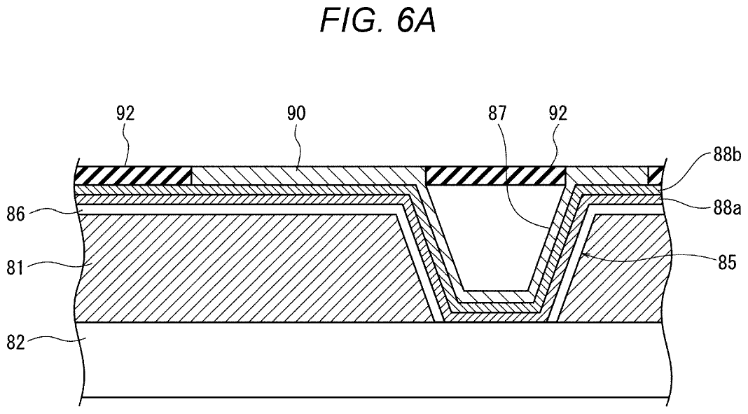

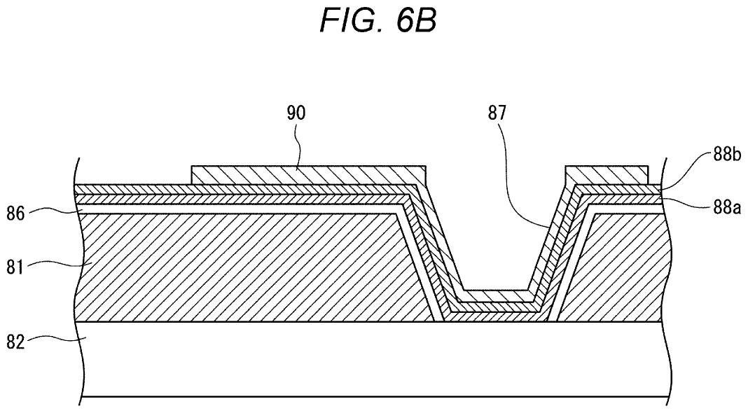

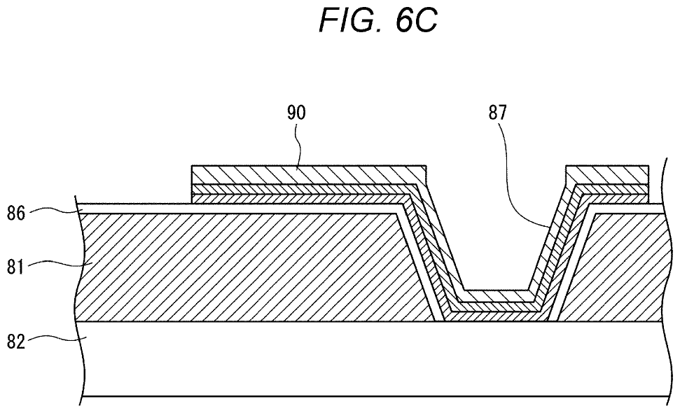

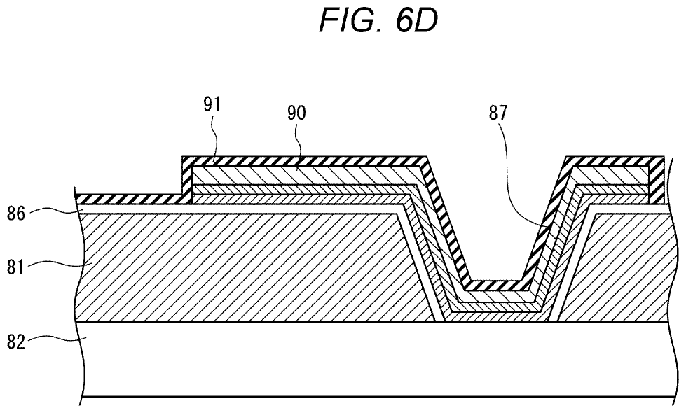

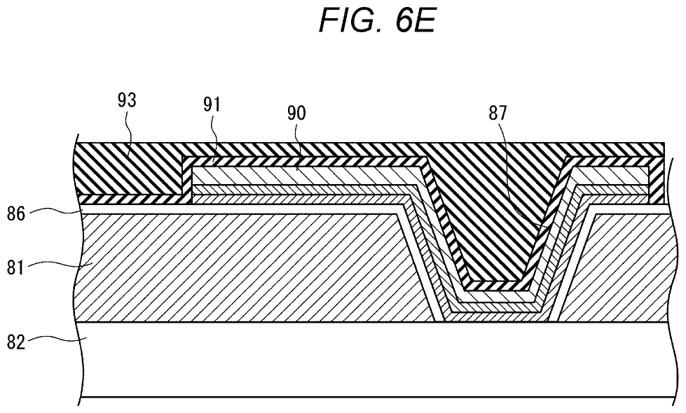

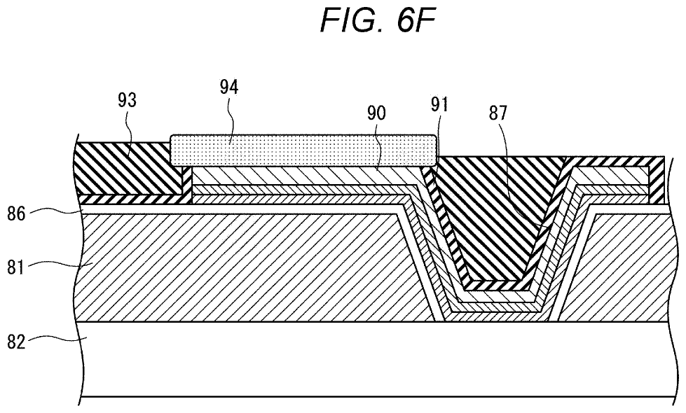

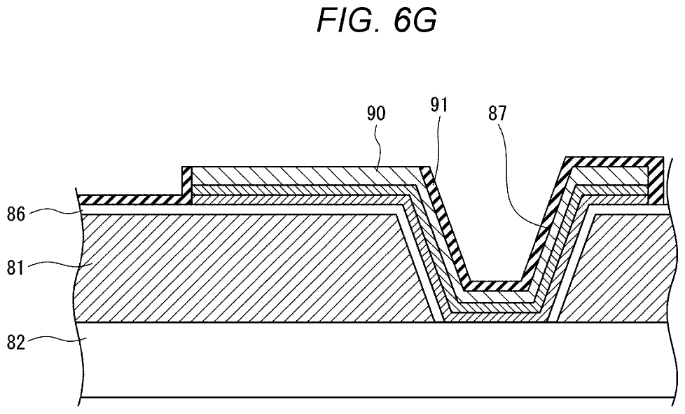

Next, a manufacturing process of the imaging device 1 according to this embodiment is described with reference to FIGS. 6A to 6G. Here, the manufacturing process regarding the passivation film 91 is described. Note that, the manufacturing processes of other than the passivation film 91 are similar to those in the related art, so that they are not described.

Although not illustrated in FIG. 6A, the plurality of wiring layers 83 and the interlayer insulating film 84 are already formed in the multilayer wiring layer 82. Furthermore, the through silicon via 87 is formed in the through hole 85 of the silicon substrate 81. In this embodiment, a seed layer 88a and a seed layer 88b are formed between the through hole 85 and the insulating film 86. The seed layer 88a is a titanium (Ti) layer, and the seed layer 88b is a copper (Cu) layer. Note that, in FIG. 5, the seed layer 88a and the seed layer 88b are not illustrated.

The through silicon via 87 can be formed by electrolytic plating of the seed layer 88b. In a process illustrated in FIG. 6A, the connection terminal 90 is formed on the seed layer 88b using a resist 92 as a mask. Similarly to the through silicon via 87, the connection terminal 90 can also be formed by electrolytic plating of the seed layer 88b.

Next, as illustrated in FIG. 6B, the resist 92 is peeled.

Next, as illustrated in FIG. 6C, exposed portions of the seed layer 88a and the seed layer 88b are removed by wet etching.

Next, as illustrated in FIG. 6D, the passivation film 91 is formed on entire surfaces of the insulating film 86, the through silicon via 87, and the connection terminal 90. The passivation film 91 can be formed by chemical vapor deposition (CVD) or atomic layer deposition (ALD). The passivation film 91 needs to have a thickness capable of covering a bottom and a side wall of the through silicon via 87 and a step between the insulating film and the connection terminal 90. In consideration of film forming time and treatment after the film forming process, the thickness of the passivation film 91 is preferably 30 nm to 50 nm. Note that, the thickness of the passivation film 91 is not limited to this range, and may be larger than 50 nm.

Next, as illustrated in FIG. 6E, a resist 93 is applied onto the passivation film 91. As the resist 93, for example, a positive resist such as an i-line resist (mercury spectrum line of a wavelength of 365 nm) can be used. The resist 93 needs to have a thickness capable of covering the step between the connection terminal 90 and the insulating film 86. Therefore, the thickness of the resist 93 is preferably approximately 10 μm to 20 μm.

Next, as illustrated in FIG. 6F, the resist 93 and the passivation film 91 covering the connection terminal 90 are polished to expose an upper surface of the connection terminal 90. In this process, for example, the resist 93 and the passivation film 91 are polished by chemical mechanical polishing (CMP) using a polishing head 94.

Next, as illustrated in FIG. 6G, the resist 93 is peeled. Therefore, one surface of the logic substrate 11 is covered with the passivation film 91 except for the upper surface of the connection terminal 90. Thereafter, the other surface of the logic substrate 11 is joined to the pixel sensor substrate 12.

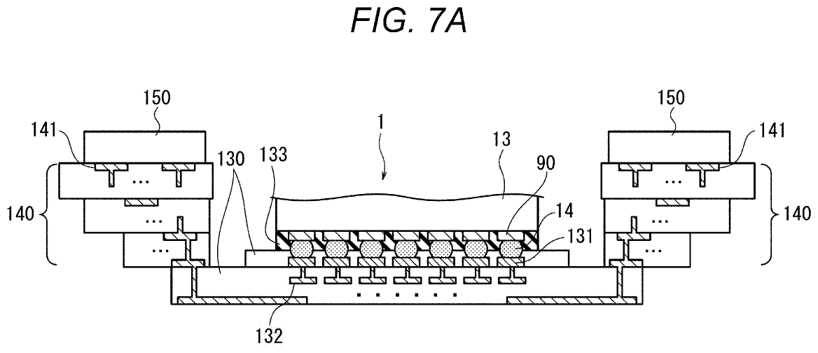

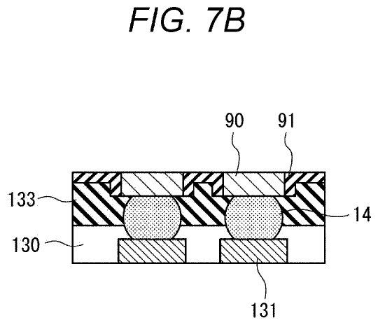

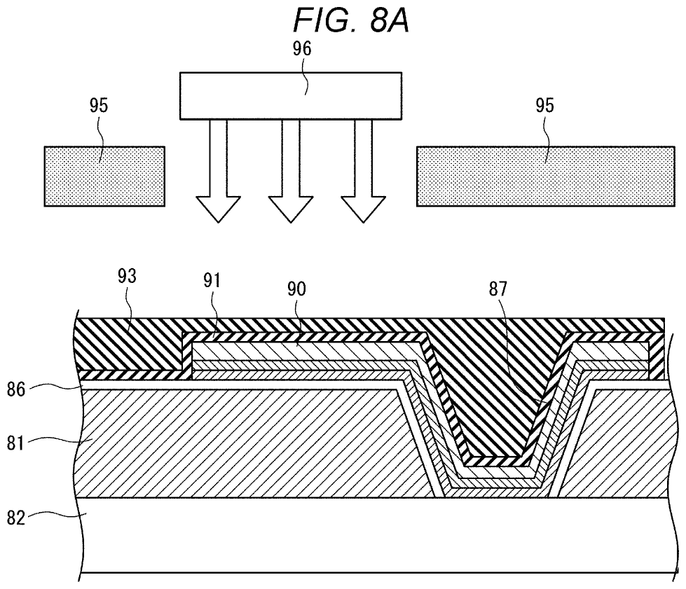

FIG. 7A is a diagram illustrating an example of a mounting state of the imaging device 1. Furthermore, FIG. 7B is a partially enlarged view of FIG. 7A.

In this embodiment, as illustrated in FIG. 7A, the imaging device 1 is accommodated in a package substrate 140 in a state of being joined to a relay substrate 130. A plurality of connection terminals 131 is formed on an upper surface of the relay substrate 130. In the relay substrate 130, a plurality of lines of wiring 132 electrically connected to the connection terminals 131, respectively, is formed in layers.

As illustrated in FIG. 7B, each connection terminal 131 is individually joined to each connection terminal 90 of the imaging device 1 via the solder ball 14. A gap between the connection terminal 90 and the connection terminal 131 is filled with an underfill material 133.

As illustrated in FIG. 7A, a plurality of lines of wiring 141 electrically connected to the respective lines of wiring 132 is also formed in layers in the package substrate 140. A control board 150 is mounted on the package substrate 140. The control board 150 is electrically connected to the uppermost wiring 141. The operation of the imaging device 1 is controlled by the control board 150.

According to this embodiment described above, the passivation film 91 is formed by using a film containing silicon. Therefore, a difference in thermal expansion coefficient between the passivation film 91 and the silicon substrate 81 is smaller than that in a case where the resin film is formed as the passivation film 91. Therefore, a stress acting on the through silicon via 87 from the passivation film 91 is alleviated. Therefore, a spot defect caused by deformation of the through silicon via 87 can be suppressed.

Furthermore, in this embodiment, a stress acting on the solder ball 14 from the passivation film 91 is also reduced. Therefore, conduction failure caused by a crack between the connection terminal 90 and the solder ball 14 can be suppressed.

Note that, a material of the passivation film 91 is not limited to a silicon compound such as silicon oxide, silicon nitride, or silicon carbonitride. There is no particular limitation as long as the material is an insulating material in which the stress acting on the through silicon via 87 and the solder ball 14 from the passivation film 91 is smaller than that of the resin, such as a material in which the difference in thermal expansion coefficient with respect to the silicon substrate 81 is smaller than that of the resin.

### Second Embodiment

A second embodiment is described focusing on differences from the first embodiment. In this embodiment, while the structure of the imaging device is similar to that of the first embodiment, a method for manufacturing the passivation film 91 is different from that of the first embodiment.

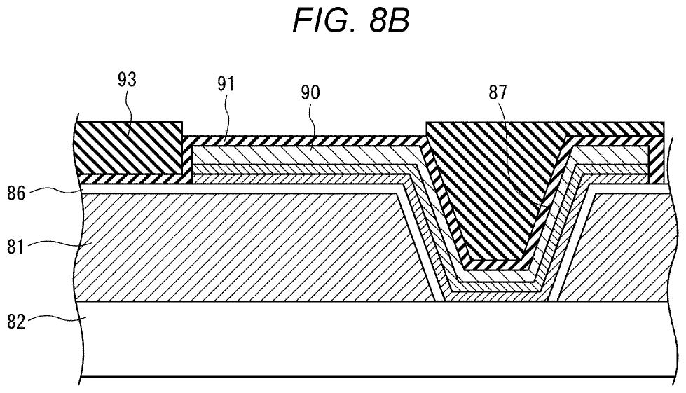

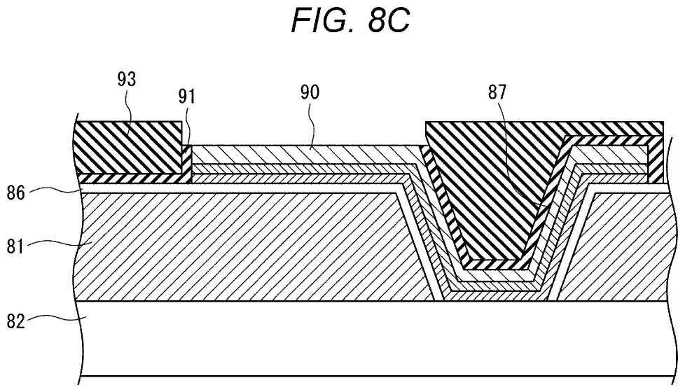

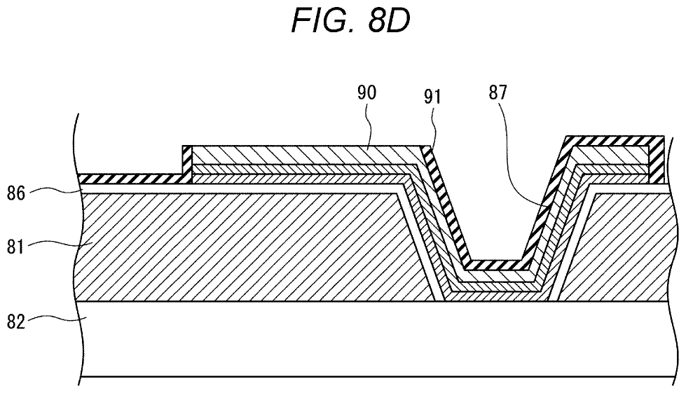

A manufacturing process of the passivation film 91 according to this embodiment is described below with reference to FIGS. 8A to 8D. Note that, processes up to a process of applying the resist 93 on the passivation film 91 (refer to FIG. 6E) are similar to those in the first embodiment, so that they are not described.

In this embodiment, after the resist 93 is applied, as illustrated in FIG. 8A, a cover portion of the connection terminal 90 out of the resist 93 is exposed using a mask 95 and an exposure device 96. The mask 95 has an opening pattern in a portion opposed to the connection terminal 90. The exposure device 96 applies light L from above the mask 95 to the resist 93. The light L passes through the opening pattern of the mask 95 and exposes the cover portion of the connection terminal 90.

Next, the resist 93 is developed. As a result, as illustrated in FIG. 8B, the cover portion of the connection terminal 90 (exposed portion) out of the resist 93 is removed.

Next, as illustrated in FIG. 8C, a portion exposed by removal of the resist 93 out of the passivation film 91 is removed. The exposed portion of the passivation film 91 can be removed by dry etching. In this etching process, for example, oxygen (O₂) gas is used in a case of etching back the resist 93. Furthermore, in a case where the passivation film 91 is a silicon oxide film, a silicon nitride film, or a silicon carbonitride film, carbon tetrafluoride (CF₄) gas is used as an etching gas.

Next, as illustrated in FIG. 8D, the resist 93 is peeled by wet etching. Therefore, one surface of the logic substrate 11 is covered with the passivation film 91 except for the upper surface of the connection terminal 90 as in the first embodiment. Thereafter, the other surface of the logic substrate 11 is joined to the pixel sensor substrate 12.

In this embodiment described above also, as in the first embodiment, the passivation film 91 contains not a resin but silicon. Therefore, the stress acting on the through silicon via 87 from the passivation film 91 is alleviated. Therefore, a spot defect caused by deformation of the through silicon via 87 can be suppressed. Moreover, the stress acting on the solder ball 14 from the passivation film 91 is also reduced. Therefore, conduction failure caused by a crack between the connection terminal 90 and the solder ball 14 can be suppressed.

### Third Embodiment

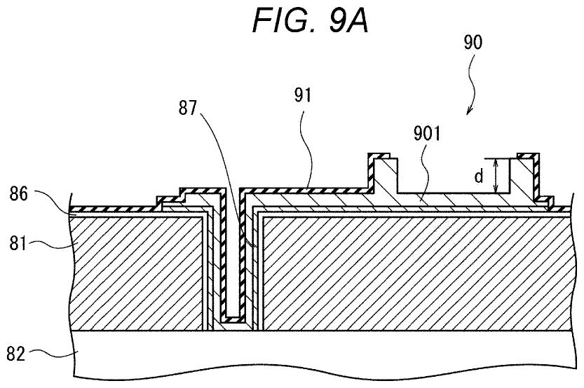

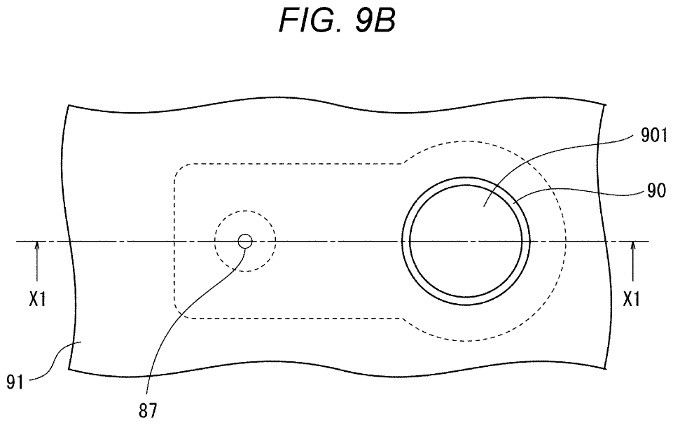

FIG. 9A is a cross-sectional view illustrating a structure of a substantial part of an imaging device according to a third embodiment. FIG. 9B is a plane view illustrating the structure of the substantial part of the imaging device according to the third embodiment. FIG. 9A is a cross-sectional view taken along cut line X1-X1 in FIG. 9B. Note that, components similar to those of the first embodiment described above are denoted by the same reference numerals, and they are not described in detail.

As illustrated in FIG. 9A, in the imaging device according to this embodiment, the connection terminal 90 includes a recess 901. The solder ball 14 is joined to the recess 901. A depth d of the recess 901 is preferably 6 μm or more in consideration of joining reliability with the solder ball 14.

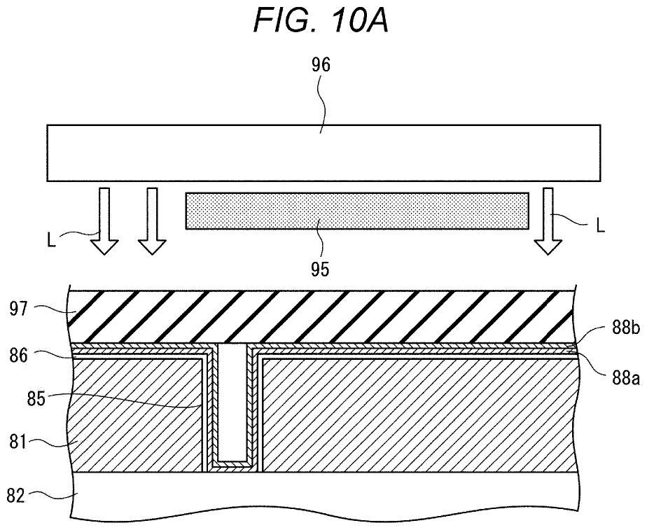

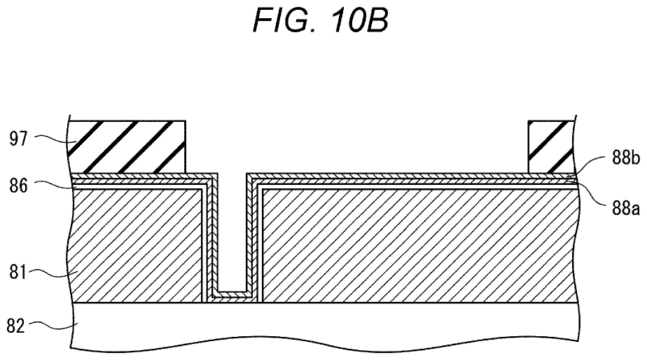

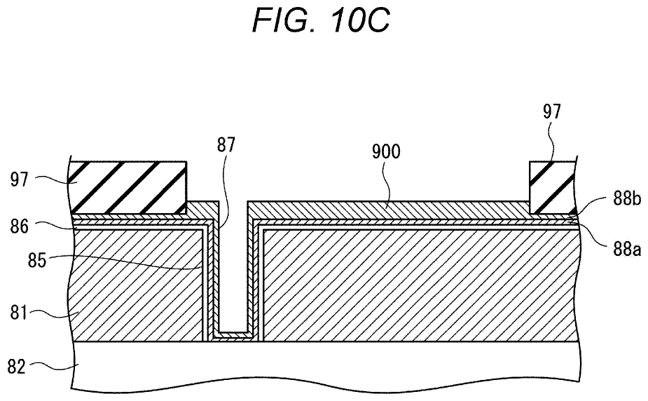

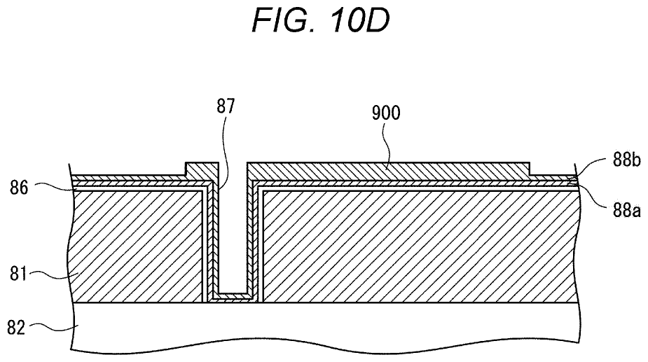

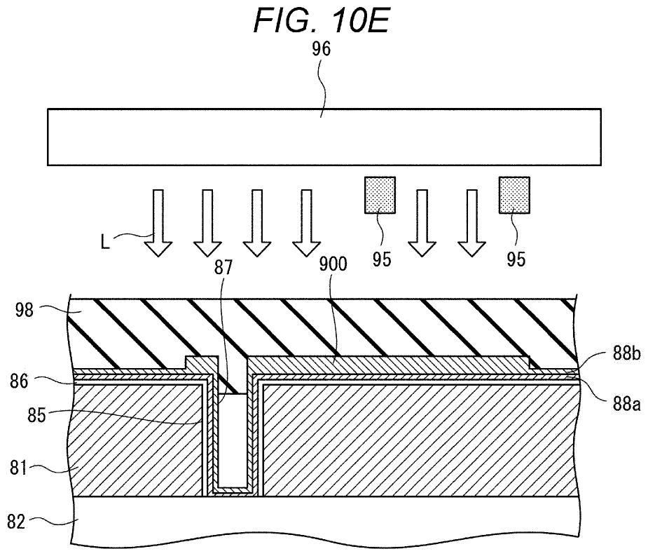

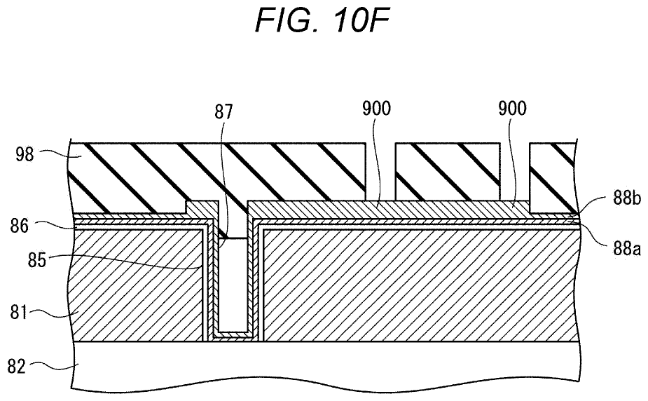

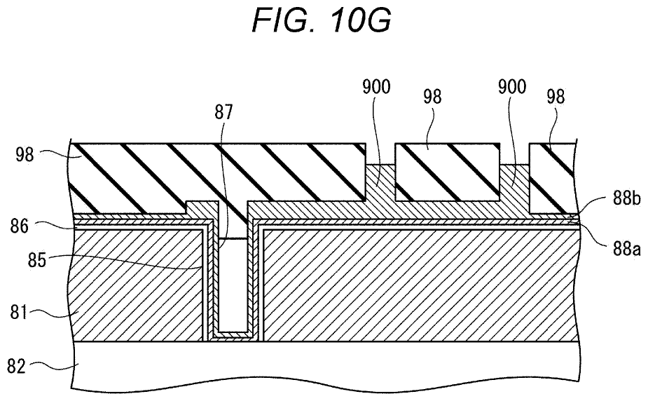

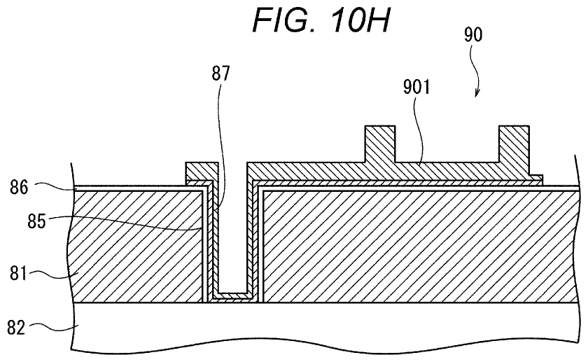

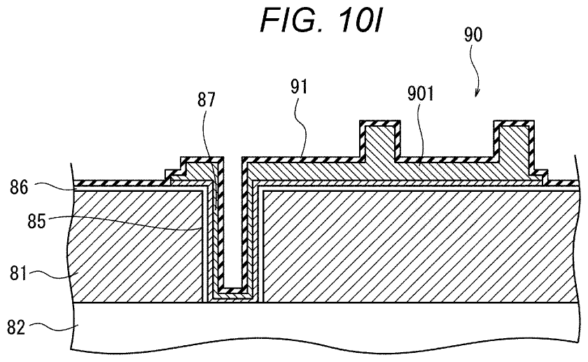

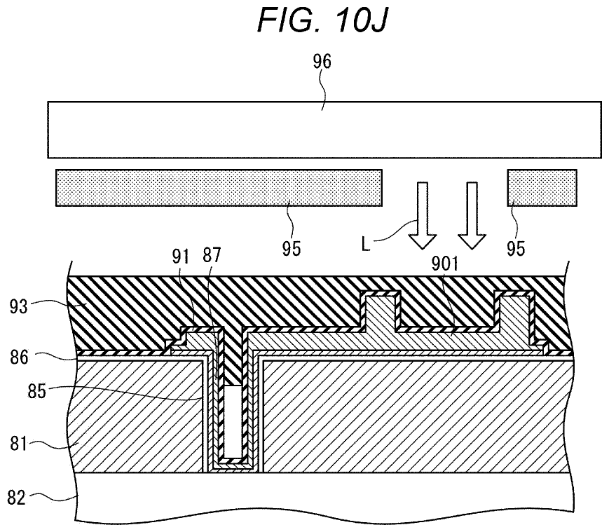

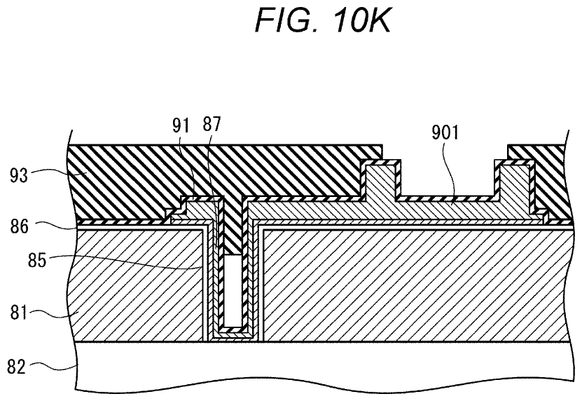

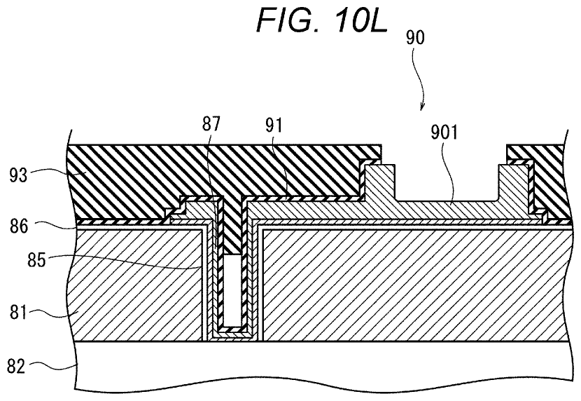

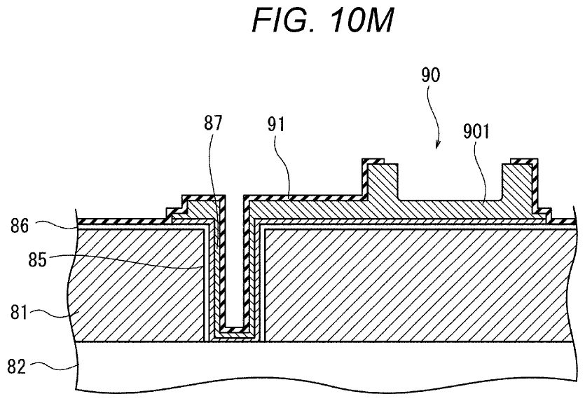

A manufacturing process of the imaging device according to this embodiment is described with reference to FIGS. 10A to 10M. Here, a process regarding manufacture of the through silicon via 87, the connection terminal 90, and the passivation film 91 is described.

First, as illustrated in FIG. 10A, a portion not covered with the mask 95 out of a resist 97 is exposed using the mask 95 and the exposure device 96. The resist 97 can be formed by applying a negative resist on the seed layer 88b. The resist 97 has a thickness of 10 to 20 μm.

Next, the resist 97 is developed. As a result, as illustrated in FIG. 10B, an unexposed portion in which the light L of the exposure device 96 out of the resist 97 is shielded by the mask 95 is removed.

Next, as illustrated in FIG. 10C, the seed layer 88b containing copper is electrolytically plated. Therefore, the through silicon via 87 is formed in the through hole 85, and a base layer 900 of the connection terminal 90 is formed.

Next, as illustrated in FIG. 10D, the resist 97 is peeled. The resist 97 can be removed by, for example, wet etching.

Next, as illustrated in FIG. 10E, a portion not covered with the mask 95 out of a resist 98 is exposed using the mask 95 and the exposure device 96. The resist 98 can be formed by applying a negative resist on the through silicon via 87 and the base layer 900. Furthermore, the mask 95 is arranged above a side wall of the recess 901 of the connection terminal 90.

Next, the resist 98 is developed. As a result, as illustrated in FIG. 10F, an unexposed portion in which the light L of the exposure device 96 is shielded by the mask 95 out of the resist 98 is removed. Therefore, a portion forming the side wall of the recess 901 out of the base layer 900 is exposed.

Next, as illustrated in FIG. 10G, the exposed portion of the base layer 900 containing copper is electrolytically plated. Therefore, the side wall of the recess 901 is completed.

Next, as illustrated in FIG. 10H, the resist 98 and the seed layer 88a and the seed layer 88b formed under the resist 98 are removed by, for example, wet etching. Therefore, the recess 901 of the connection terminal 90 is completed.

Next, as illustrated in FIG. 10L the passivation film 91 is formed on entire surfaces of the insulating film 86, the through silicon via 87, and the connection terminal 90. The passivation film 91 can be formed by CVD or ALD as in the first embodiment.

Next, as illustrated in FIG. 10J, a portion not covered with the mask 95 out of the resist 93 applied on the passivation film 91 is exposed using the mask 95 and the exposure device 96. As the resist 93, as in the first embodiment, a positive resist such as an i-line resist (mercury spectrum line of a wavelength of 365 nm) can be used. Furthermore, in this embodiment, the mask 95 has a pattern opened in a portion opposed to a bottom of the recess 901 of the connection terminal 90.

Next, as illustrated in FIG. 10K, the resist 93 is developed. As a result, as illustrated in FIG. 10K, an exposed portion of the resist 93 is removed.

Next, as illustrated in FIG. 10L, an exposed portion exposed by removal out of the exposed portion of the resist 93 of the passivation film 91 is removed. The exposed portion of the passivation film 91 can be removed by dry etching, for example.

Next, as illustrated in FIG. 10M, the resist 93 is peeled by wet etching. Therefore, one surface of the logic substrate 11 is covered with the passivation film 91 except for the recess 901 of the connection terminal 90.

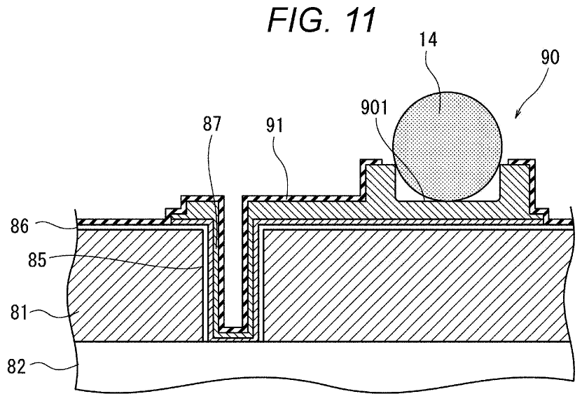

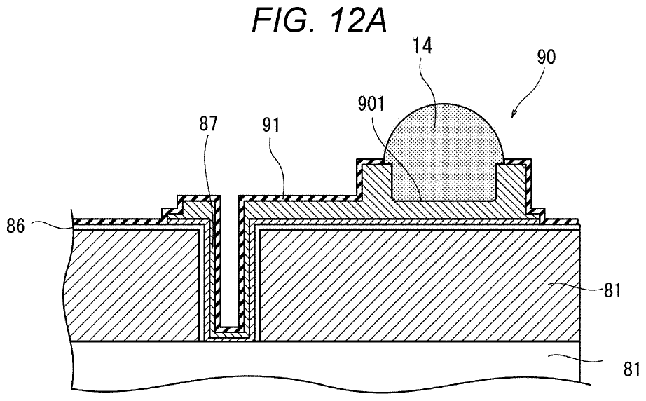

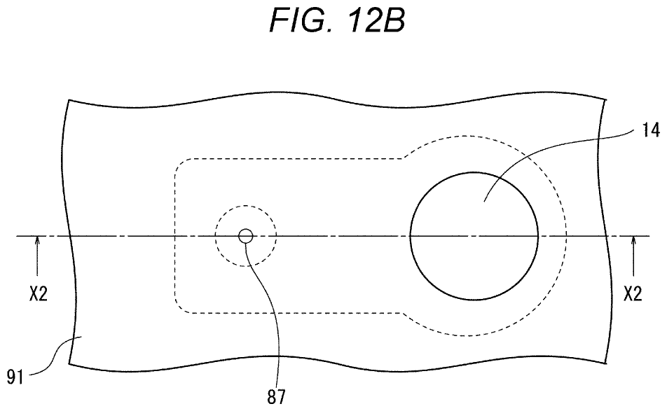

FIG. 11 is a cross-sectional view illustrating a shape of the solder ball 14 before being joined to the relay substrate 130. Furthermore, FIG. 12A is a cross-sectional view illustrating a shape of the solder ball 14 after being joined to the relay substrate 130. FIG. 12B is a plane view illustrating the shape of the solder ball 14 after being joined to the relay substrate 130. FIG. 12A is a cross-sectional view taken along cut line X2-X2 in FIG. 12B.

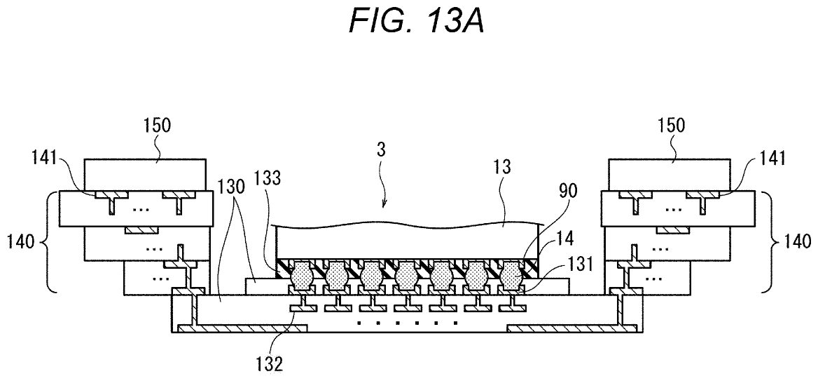

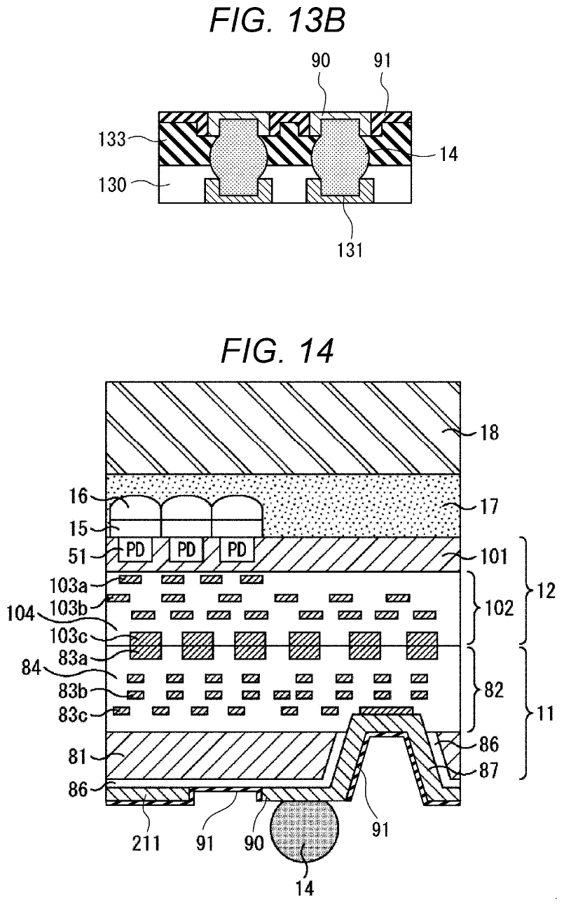

Furthermore, FIG. 13A is a diagram illustrating an example of a mounting state of an imaging device 3 according to this embodiment. Furthermore, FIG. 13B is a partially enlarged view of FIG. 13A.

As illustrated in FIG. 11, the solder ball 14 is welded to the connection terminal 90. Furthermore, in this embodiment, as illustrated in FIG. 13A, the imaging device 3 is accommodated in the package substrate 140 in a state of being joined to the relay substrate 130 as in the first embodiment. As the solder ball 14 is joined to the relay substrate 130, this is deformed as illustrated in FIG. 12A. At that time, as illustrated in FIGS. 12A and 13B, a portion other than the recess 901 is covered with the passivation film 91. Therefore, as illustrated in FIG. 12B, diffusion of solder from the solder ball 14 can be avoided.

In this embodiment described above also, as in the first embodiment, the passivation film 91 contains not a resin but silicon. Therefore, the stress acting on the through silicon via 87 from the passivation film 91 is alleviated. Therefore, a spot defect caused by deformation of the through silicon via 87 can be suppressed. Furthermore, the stress acting on the solder ball 14 from the passivation film 91 is also reduced. Therefore, conduction failure caused by a crack between the connection terminal 90 and the solder ball 14 can be suppressed.

Moreover, in this embodiment, since the recess 901 is formed on the connection terminal 90, the solder ball 14 may be easily aligned. In addition, diffusion of the solder can be avoided when the imaging device is joined to the relay substrate 130.

### Fourth Embodiment

FIG. 14 is a cross-sectional view illustrating a schematic structure of an imaging device according to a fourth embodiment. Components similar to those of the first embodiment described above are denoted by the same reference numerals, and they are not described in detail.

In this embodiment, a method for connecting the logic substrate 11 to the pixel sensor substrate 12 is different from that in the first embodiment illustrated in FIG. 5.

In the first embodiment, as illustrated in FIG. 5, the logic substrate 11 and the pixel sensor substrate 12 are connected to each other by using two through silicon vias of a through silicon via 151 and a through silicon via 152. In contrast, in this embodiment, they are connected to each other by metal bonding of metal (for example, copper) contained in the wiring layer 83a of the logic substrate 11 and metal (for example, copper) contained in the wiring layer 103c of the pixel sensor substrate 12.

Note that, in the imaging device according to this embodiment also, as in the first embodiment, the through silicon via 87 is connected to the lowermost wiring layer 83c of the logic substrate 11, so that the solder ball 14 is connected to the wiring layer 83 and the wiring layer 103 in the laminated substrate 13.

In contrast, in this embodiment, dummy wiring 211 that is not electrically connected anywhere is formed on the lower surface side of the silicon substrate 81 in the same layer as the connection terminal 90 to which the solder ball 14 is connected, using the same wiring material as that of the connection terminal 90.

In this embodiment described above also, as in the first embodiment, the passivation film 91 contains not a resin but silicon. Therefore, the stress acting on the through silicon via 87 from the passivation film 91 is alleviated. Therefore, a spot defect caused by deformation of the through silicon via 87 can be suppressed. Furthermore, the stress acting on the solder ball 14 from the passivation film 91 is also reduced. Therefore, conduction failure caused by a crack between the connection terminal 90 and the solder ball 14 can be suppressed.

Moreover, in this embodiment, the dummy wiring 211 reduces an influence of unevenness at the time of metal bonding between the wiring layer 83a on the logic substrate 11 side and the wiring layer 103c on the pixel sensor substrate 12 side. At the time of metal bonding, if the connection terminal 90 is formed only in a partial region of the lower surface of the silicon substrate 81, unevenness occurs by a difference in thickness due to the presence or absence of the connection terminal 90. Therefore, by providing the dummy wiring 211, the influence of the unevenness can be reduced.

### Fifth Embodiment

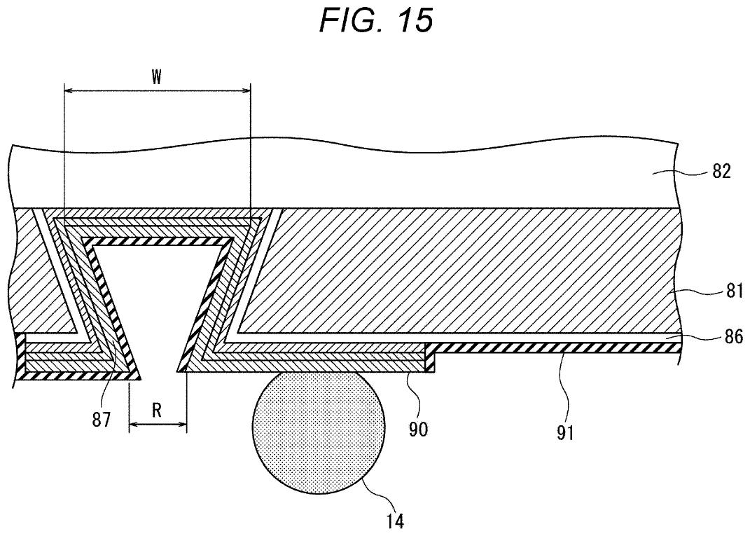

FIG. 15 is a cross-sectional view illustrating a structure of a substantial part of an imaging device according to a fifth embodiment. Components similar to those of the first embodiment described above are denoted by the same reference numerals, and they are not described in detail.

In this embodiment, a shape of the through silicon via 87 is different from that of the first embodiment. The through silicon via 87 according to the first embodiment has a reverse tapered shape in which an opening diameter R is wider than a bottom width W. In contrast, the through silicon via 87 according to this embodiment has a tapered shape in which the opening diameter R is narrower than the bottom width W.

In this embodiment also, the passivation film 91 containing silicon is formed by CVD or ALD as in other embodiments. Therefore, even if the through silicon via 87 has the reverse tapered shape with the narrow opening diameter R, the passivation film 91 can be formed on the surface of the through silicon via 87.

Therefore, in this embodiment also, the stress acting on the through silicon via 87 from the passivation film 91 is alleviated as in the other embodiments. Therefore, a spot defect caused by deformation of the through silicon via 87 can be suppressed. Furthermore, since the stress acting on the solder ball 14 from the passivation film 91 is also reduced, conduction failure caused by a crack between the connection terminal 90 and the solder ball 14 can be suppressed.

Note that, in the first to fifth embodiments described above, the substrate has a structure obtained by stacking the logic substrate 11 and the pixel sensor substrate 12, but this may have a single-layer structure. Furthermore, a memory circuit including a memory element may be arranged on the pixel sensor substrate 12 in place of the pixel circuit 21.

<Application Example to Mobile Body>

The technology according to an embodiment of the present disclosure (present technology) can be applied to various products. For example, the technology according to an embodiment of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

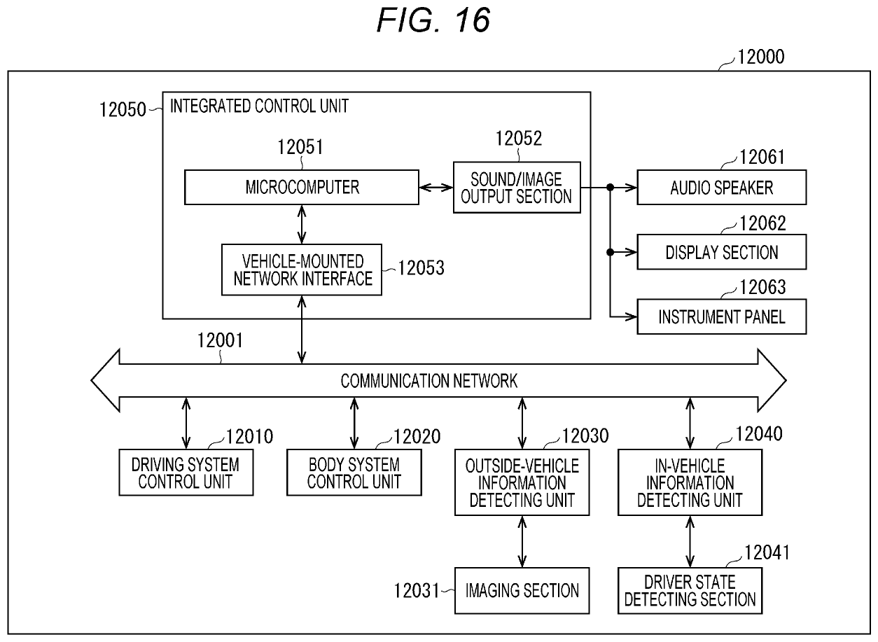

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example illustrated in FIG. 16, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display or a head-up display.

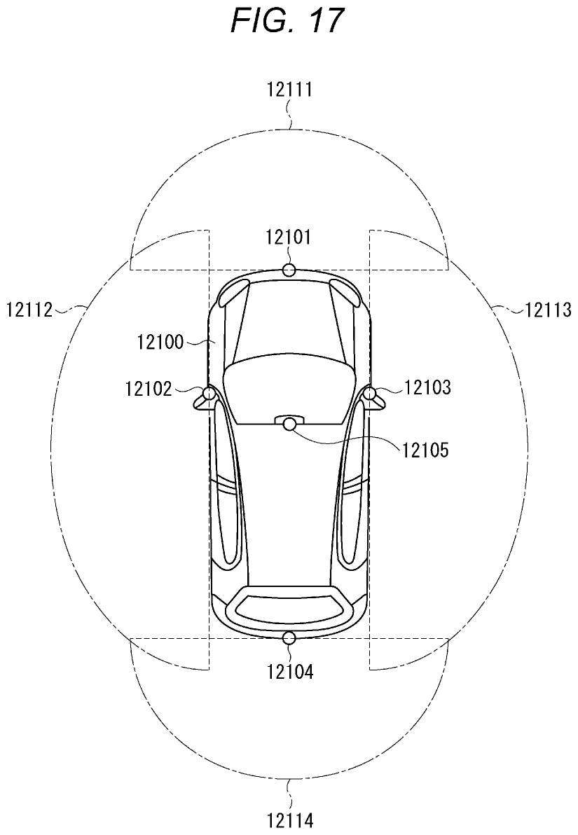

FIG. 17 is a diagram depicting an example of an installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions such as a front nose, sideview mirrors, a rear bumper, and a back door of the vehicle 12100 as well as an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 17 depicts an example of imaging ranges of the imaging sections 12101 to 12104. An imaging range 12111 represents the imaging range of the imaging section 12101 provided to the front nose. Imaging ranges 1211212113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been described above. The technology according to an embodiment of the present disclosure can be applied to, for example, the imaging section 12031 in the configuration described above. Specifically, the imaging devices described in the first to fourth embodiments can be applied to the imaging section 12031. By applying the technology according to an embodiment of the present disclosure, an imaged image with higher reliability can be obtained, so that safety can be improved.

Note that, the present technology can have the following configurations.

(1) An imaging device including:
a substrate;
a pixel circuit provided on the substrate;
a through silicon via that penetrates the substrate and is electrically connected to the pixel circuit; and
a passivation film that covers the through silicon via, in which
the passivation film contains at least silicon.

(2) The imaging device according to (1), in which
the passivation film contains silicon oxide (SiO₂), silicon nitride (SiN), or silicon carbonitride (SiCN).

(3) The imaging device according to (1), in which
the passivation film contains a porous low-k material.

(4) The imaging device according to (3), in which
the porous low-k material is fluorine-doped silicon oxide (SiOF) or carbon-doped silicon oxide (SiOC).

(5) The imaging device according to any one of (1) to (4), in which
a thickness of the passivation film is 30 nm to 50 nm.

(6) The imaging device according to any one of (1) to (6), in which
the substrate includes a first substrate and a second substrate stacked on the first substrate,
the pixel circuit is provided on the first substrate, and
the through silicon via is provided on the second substrate.

(7) The imaging device according to (6), in which
the through silicon via has a recessed shape recessed toward the first substrate.

(8) The imaging device according to (7), in which
the through silicon via has a tapered shape in which an opening diameter of the recessed shape is narrower than a bottom width of the recessed shape.

(9) The imaging device according to any one of (6) to (8), further including:
a connection terminal that protrudes from the second substrate and is electrically connected to the through silicon via, in which
the passivation film covers a side surface of the connection terminal.

(10) An imaging device including:
a substrate;
a pixel circuit provided on the substrate;
a connection terminal that protrudes from the substrate; and
a passivation film that covers a side surface of the connection terminal, in which
the passivation film contains at least silicon.

(11) The imaging device according to (10), in which
the passivation film contains silicon oxide (SiO₂), silicon nitride (SiN), or silicon carbonitride (SiCN).

(12) The imaging device according to (10), in which
the passivation film contains a porous low-k material.

(13) The imaging device according to (12), in which
the porous low-k material is fluorine-doped silicon oxide (SiOF) or carbon-doped silicon oxide (SiOC).

(14) The imaging device according to any one of (10) to (13), in which
a thickness of the passivation film is 30 nm to 50 nm.

(15) The imaging device according to (10), in which
the substrate includes a first substrate and a second substrate stacked on the first substrate,
the pixel circuit is provided on the first substrate, and
the connection terminal is provided on the second substrate.

(16) The imaging device according to (15), in which
the connection terminal includes a recess, and a solder ball is welded to the recess.

(17) A method for manufacturing an imaging device, the method including:
forming a through silicon via that penetrates a substrate and is electrically connected to a pixel circuit; and
covering the through silicon via with a passivation film containing at least silicon.

(18) The method for manufacturing the imaging device according to (17), the method including:
forming the passivation film by chemical vapor deposition (CVD) or atomic layer deposition (ALD).

(19) The method for manufacturing the imaging device according to (17) or (18), in which the passivation film contains silicon oxide (SiO₂), silicon nitride (SiN), or silicon carbonitride (SiCN).

(20) The method for manufacturing the imaging device according to (17) or (18), in which the passivation film contains a porous low-k material.

### REFERENCE SIGNS LIST

1, 3 Imaging device
11 Logic substrate
12 Pixel sensor substrate
13 Laminated substrate
21 Pixel circuit
81 Silicon substrate
87 Through silicon via
90 Connection terminal
91 Passivation film

What is claimed is:

1. An imaging device comprising:
a substrate;
a pixel circuit provided on the substrate;
a through silicon via that penetrates the substrate and is electrically connected to the pixel circuit; and
a passivation film that covers the through silicon via, wherein
the passivation film contains at least silicon.

2. The imaging device according to claim 1, wherein
the passivation film contains silicon oxide (SiO₂), silicon nitride (SiN), or silicon carbonitride (SiCN).

3. The imaging device according to claim 1, wherein
the passivation film contains a porous low-k material.

4. The imaging device according to claim 3, wherein
the porous low-k material is fluorine-doped silicon oxide (SiOF) or carbon-doped silicon oxide (SiOC).

5. The imaging device according to claim 1, wherein
a thickness of the passivation film is 30 nm to 50 nm.

6. The imaging device according to claim 1, wherein
the substrate includes a first substrate and a second substrate stacked on the first substrate,
the pixel circuit is provided on the first substrate, and
the through silicon via is provided on the second substrate.

7. The imaging device according to claim 6, wherein
the through silicon via has a recessed shape recessed toward the first substrate.

8. The imaging device according to claim 7, wherein
the through silicon via has a tapered shape in which an opening diameter of the recessed shape is narrower than a bottom width of the recessed shape.

9. The imaging device according to claim 6, further comprising:
a connection terminal that protrudes from the second substrate and is electrically connected to the through silicon via, wherein
the passivation film covers a side surface of the connection terminal.

10. An imaging device comprising:
a substrate;
a pixel circuit provided on the substrate;
a connection terminal that protrudes from the substrate; and
a passivation film that covers a side surface of the connection terminal, wherein
the passivation film contains at least silicon.

11. The imaging device according to claim 10, wherein
the passivation film contains silicon oxide (SiO₂), silicon nitride (SiN), or silicon carbonitride (SiCN).

12. The imaging device according to claim 10, wherein
the passivation film contains a porous low-k material.

13. The imaging device according to claim 12, wherein
the porous low-k material is fluorine-doped silicon oxide (SiOF) or carbon-doped silicon oxide (SiOC).

14. The imaging device according to claim 10, wherein
a thickness of the passivation film is 30 nm to 50 nm.

15. The imaging device according to claim 10, wherein
the substrate includes a first substrate and a second substrate stacked on the first substrate,
the pixel circuit is provided on the first substrate, and
the connection terminal is provided on the second substrate.

16. The imaging device according to claim 15, wherein
the connection terminal includes a recess, and a solder ball is welded to the recess.

17. A method for manufacturing an imaging device, the method comprising:
forming a through silicon via that penetrates a substrate and is electrically connected to a pixel circuit; and
covering the through silicon via with a passivation film containing at least silicon.

18. The method for manufacturing the imaging device according to claim 17, the method comprising:
forming the passivation film by chemical vapor deposition (CVD) or atomic layer deposition (ALD).

19. The method for manufacturing the imaging device according to claim 17, wherein
the passivation film contains silicon oxide (SiO₂), silicon nitride (SiN), or silicon carbonitride (SiCN).

20. The method for manufacturing the imaging device according to claim 17, wherein
the passivation film contains a porous low-k material.
